(19) United States
(12) Patent Application Publication
(10) Pub. No.: US 2011/0241167 A1
(43) Pub. Date: Oct. 6, 2011

(54) Semiconductor Device Comprising a Capacitor in the Metallization System Formed by a Hard Mask Patterning Regime

(75) Inventors: Frank Feustel, Dresden (DE); Thomas Werner, Moritzburg (DE); Kai Frohberg, Niederau (DE)

(73) Assignee: GLOBALFOUNDRIES INC., Grand Cayman (KY)

(21) Appl. No.: 12/942,664

(22) Filed: Nov. 9, 2010

(30) Foreign Application Priority Data
Mar. 31, 2010 (DE) 10 2010 003 560.2

(51) Int. Cl. H01L 29/92; H01L 21/768; H01L 21/02

(52) U.S. Cl. 257/532; 438/637; 438/386; 257/E21.585; 257/E21.008; 257/E29.343

(57) ABSTRACT

Capacitors may be formed in the metallization system of semiconductor devices without requiring a modification of the hard mask patterning process for forming vias and trenches in the dielectric material of the metallization layer under consideration. To this end, a capacitor opening is formed prior to actually forming the hard mask for patterning the trench and via openings, wherein the hard mask material may thus preserve integrity of the capacitor opening and may remain as a portion of the electrode material after filling in the conductive material for the metal lines, vias and the capacitor electrode.

### BACKGROUND OF THE INVENTION

1. Field of the Invention

The present disclosure generally relates to the field of fabricating integrated circuits, and, more particularly, to forming capacitors in the metallization system, such as capacitors for dynamic random access memories (DRAMs), decoupling capacitors and the like.

2. Description of the Related Art

In modern integrated circuits, a very high number of individual circuit elements, such as field effect transistors in the form of CMOS, NMOS, PMOS elements, resistors, capacitors and the like, are formed on a single chip area. Typically, feature sizes of these circuit elements are steadily decreasing with the introduction of every new circuit generation, to provide currently available integrated circuits with high performance in terms of speed and/or power consumption. A reduction in size of transistors is an important aspect in steadily improving device performance of complex integrated circuits, such as CPUs. The reduction in size commonly brings about an increased switching speed, thereby enhancing signal processing performance while, however, increasing dynamic power consumption of the individual transistors. That is, due to the reduced switching time interval, the transient currents upon switching a MOS transistor element from logic low to logic high are significantly increased.

In addition to the large number of transistor elements, a plurality of passive circuit elements, such as capacitors, are typically formed in integrated circuits that are used for a plurality of purposes, such as charge storage for storing information, for decoupling and the like. Decoupling in integrated circuits is an important aspect for reducing the switching noise of the fast switching transistors, since the decoupling capacitor may provide energy at a specific point of the circuitry, for instance at the vicinity of a fast switching transistor, and thus reduce voltage variations caused by the high transient currents which may otherwise unduly affect the logic state represented by the transistor.

Due to the decreased dimensions of circuit elements, not only the performance of the individual transistor elements may be increased, but also their packing density may be improved, thereby providing the potential for incorporating increased functionality into a given chip area. For this reason, highly complex circuits have been developed, which may include different types of circuits, such as analog circuits, digital circuits and the like, thereby providing entire systems on a single chip (SoC). Furthermore, in sophisticated micro-controller devices, an increasing amount of storage capacity may be provided on chip with the CPU core, thereby also significantly enhancing the overall performance of modern computer devices. For example, in typical micro-controller designs, different types of storage devices may be incorporated so as to provide an acceptable compromise between die area consumption and information storage density versus operating speed. For instance, fast or temporary memories, so-called cache memories, may be provided in the vicinity of the CPU core, wherein respective cache memories may be designed so as to allow reduced access times compared to external storage devices. Since a reduced access time for a cache memory may typically be associated with a reduced storage density thereof, the cache memories may be arranged according to a specified memory hierarchy, wherein a level 1 cache memory may represent the memory formed in accordance with the fastest available memory technology. For example, static RAM memories may be formed on the basis of registers, thereby enabling an access time determined by the switching speed of the corresponding transistors in the registers. Typically a plurality of transistors may be required so as to implement a corresponding static RAM cell, thereby significantly reducing the information storage density compared to, for instance, dynamic RAM (DRAM) memories including a storage capacitor in combination with a pass transistor. Thus, a higher information storage density may be achieved with DRAMs, although at a reduced access time compared to static RAMs, which may nevertheless render dynamic RAMs attractive for specific less time-critical applications in complex semiconductor devices. For example, typical cache memories of level 3 may be implemented in the form of dynamic RAM memories so as to enhance information density within the CPU, while only moderately sacrificing overall performance.

Frequently, the storage capacitors may be formed in the transistor level using a vertical or planar configuration. While the planar architecture may require significant silicon area for obtaining the required capacitance values, the vertical arrangement may necessitate complex patterning regimes for forming the trenches of the capacitors.

To this end, typically, an appropriate process sequence may be implemented into the overall manufacturing flow which, however, may be substantially independent from any other processes for forming transistors, thereby requiring additional resources, which may result in reduced throughput and thus increased overall manufacturing costs. For example, at least two additional lithography steps may be required for forming the corresponding deep trenches, which may then accommodate an appropriate capacitor dielectric and capacitor electrode material that extends deeply into the semiconductor material in order to obtain the desired high capacitance. Moreover, very complex etch processes may have to be performed when etching the deep trenches into the semiconductor material, which may also affect other device areas unless significant efforts are made in order to appropriately mask these device areas. Furthermore, silicon-on-insulator (SOI) devices and bulk devices may require very different etch approaches in order to obtain the corresponding deep trenches for sophisticated capacitors, such as DRAM capacitors, decoupling capacitors and the like.

For these reasons, in some approaches, capacitors may be formed in the metallization level of semiconductor devices, thereby avoiding the complex process sequence in the transistor level, as indicated above. In advanced semiconductor devices formed on the basis of highly conductive metals, such as copper, possibly in combination with low-k dielectric materials, however, the additional processes and materials used for the capacitors may also affect other components in the metallization level, thereby possibly also compromising performance of the entire metallization system. For example, low-k dielectric materials, i.e., materials having a dielectric constant of 3.0 and less, may experience a significant material degradation upon being exposed to reactive ambients, such as etch processes, cleaning processes and the like, which are typically associated with lithography processes. Consequently, any additional lithography process may contribute to inferior performance of the metallization system. Consequently, although generally the provision of capacitors in the metallization system of advanced semiconductor devices may provide certain advantages with respect to the complex manufacturing sequence in the device level, the application of two or more lithography steps and associated etch processes and the like may nevertheless result in additional overall complexity and reduced overall performance of the metallization system.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which capacitors, such as decoupling capacitors, storage capacitors for memory areas and the like, may be efficiently provided in the metallization system of a semiconductor device without unduly contributing to overall process complexity. To this end, the capacitors may be formed on the basis of a process sequence that is compatible with the patterning sequence applied to a metallization layer in order to form vias and metal lines therein. That is, typically, in complex semiconductor devices, the overall reduced dimensions in the device level may require reduced and precisely defined lateral dimensions of the metal structures in the metallization system, wherein, typically, sophisticated hard mask materials may be used for patterning the dielectric material of the metallization layer under consideration. For this purpose, frequently, metal-containing hard mask materials, such as titanium nitride, tantalum, tantalum nitride and the like, may be used which have a high etch resistivity and thus allow a precise patterning of dielectric materials during plasma-based anisotropic etch processes without requiring an undue layer thickness of the hard mask material. On the other hand, the hard mask materials may be efficiently removed during the further processing, for instance when also removing any excess materials, such as copper, barrier materials and the like. According to the principles disclosed herein, the concept of using sophisticated hard mask materials for patterning the interconnect structures in the metallization layer may be applied in a well-established efficient manner without interference by the concurrent formation of a capacitor electrode in the metallization layer under consideration. In some illustrated aspects disclosed herein, the hard mask material may be applied in the presence of a capacitor opening so that, after patterning of the hard mask material, the capacitor opening may have formed therein a very efficient etch stop material, which may also be preserved during the further processing and which may not unduly affect the functional behavior of the corresponding capacitor electrode after filling in one or more conductive materials as required for completing the interconnect structures of the metallization layer under consideration. Consequently, capacitors may be provided on the basis of well-established materials and process strategies, thereby requiring only one additional lithography step, which may thus provide superior process efficiency, while at the same time achieving superior overall performance of the resulting metallization system compared to conventional strategies.

One illustrative method disclosed herein comprises forming a first opening in a dielectric material of a first metallization layer of a semiconductor device, wherein the first opening is positioned above a first metal region formed in a second metallization layer that is formed below the first metallization layer. Furthermore, the first opening is separated from the first metal region by an insulating layer. The method further comprises forming a conductive hard mask material above the dielectric material of the first metallization layer and above inner surface areas of the first opening. The method additionally comprises patterning the conductive hard mask material so as to form a hard mask that defines a size and position of a second opening to be formed in the dielectric material of the metallization layer. Furthermore, the method comprises forming the second opening in the dielectric material of the first metallization layer by using the hard mask as an etch stop material. Additionally, the method comprises filling the first and second openings with a metal-containing material in a common fill process.

A further illustrative method disclosed herein relates to forming a capacitive structure in a metallization system of a semiconductor device. The method comprises forming a capacitor opening in a dielectric layer by performing a first etch process, wherein the capacitor opening is separated from a first capacitor region by a dielectric material. The method further comprises forming a hard mask above the dielectric layer and in the capacitor opening, wherein the hard mask defines a size and position of a trench. Moreover, the method comprises forming a via opening and the trench by performing a second etch process and using the hard mask as an etch stop material. Additionally, the method comprises filling the via opening, the trench and the capacitor opening with a metal-containing material in a common process sequence so as to form a via, a metal line connected thereto and a second capacitor region.

One illustrative semiconductor device disclosed herein comprises a first metallization layer comprising a first dielectric material and a first metal region embedded in the first dielectric material, wherein the first metal region represents a first capacitor electrode. The semiconductor device further comprises a second metallization layer formed below the first metallization layer and comprising a second dielectric material, wherein the second metallization layer comprises a second metal region that is located below the first metal region and that represents a second capacitor electrode. Additionally, the semiconductor device comprises a capacitor dielectric material formed on sidewalls and a bottom of the first metal region.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1i schematically illustrate cross-sectional views of a semiconductor device during various manufacturing stages when forming a capacitor in a metallization system of the semiconductor device on the basis of a patterning regime using a hard mask for forming vias and trenches in a metallization layer of the semiconductor device, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides semiconductor devices and manufacturing techniques in which metal lines and vias may be formed on the basis of an efficient hard mask regime, which may be applied in the presence of a capacitor opening, wherein the hard mask material may act as an efficient etch stop material in the capacitor opening upon patterning a via opening and a trench on the basis of any appropriate process strategy. In some illustrative embodiments, the hard mask material may be provided in the form of a conductive metal-containing material, which may have very high etch resistivity with respect to anisotropic etch recipes that are typically applied so as to pattern a low-k dielectric material and any etch stop materials in metallization systems of semiconductor devices so that superior integrity of the capacitor opening may be preserved, while at the same time the hard mask material does not need to be removed from the capacitor opening after the patterning process. Furthermore, if required, an appropriate dielectric material may be provided in the capacitor opening prior to the deposition of the hard mask material, which may thus enable a precise determination of the overall electrical characteristics, that is, the capacitance, since the lateral size of the opening as well as the thickness and composition of the capacitor dielectric may be selected with a high degree of accuracy since well-established material systems and deposition techniques may be applied, while the hard mask material of superior etch resistivity may preserve integrity of any underlying materials. For example, in sophisticated process strategies for forming semiconductor devices, frequently, high-k dielectric materials, i.e., dielectric materials having a dielectric constant of 10.0 or higher, may be used for forming sophisticated high-k metal gate electrode structures so that corresponding resources in terms of materials and process tools are typically available in corresponding manufacturing environments. Consequently, such materials and process tools may also be advantageously used for forming the capacitor in the metallization system, while a high degree of compatibility with respect to efficient patterning strategies for forming metal lines and vias may also be preserved. For example, in some illustrative embodiments, only one additional lithography process may be required for forming an appropriate opening in the dielectric material prior to applying the desired patterning strategy for the vias and trenches in the metallization layer, thereby providing superior advantages compared to conventional strategies when forming capacitors in the device level or in the metallization system when using conventional independent separate process modules.

Consequently, capacitors, such as decoupling capacitors, storage capacitors for dynamic RAM areas and the like, may be implemented in the metallization system substantially without interfering with the overall complex patterning process for forming the metal interconnect structures in the metallization system. Furthermore, due to the superior etch resistivity of hard mask materials that are typically used for patterning the metal interconnect structures, the electronic characteristics of the capacitors may be defined on the basis of well-established anisotropic etch processes for patterning the dielectric material of the metallization system, wherein a desired high capacitance may be achieved on the basis of high-k dielectric materials, if desired, thereby reducing the overall area consumption in the metallization system.

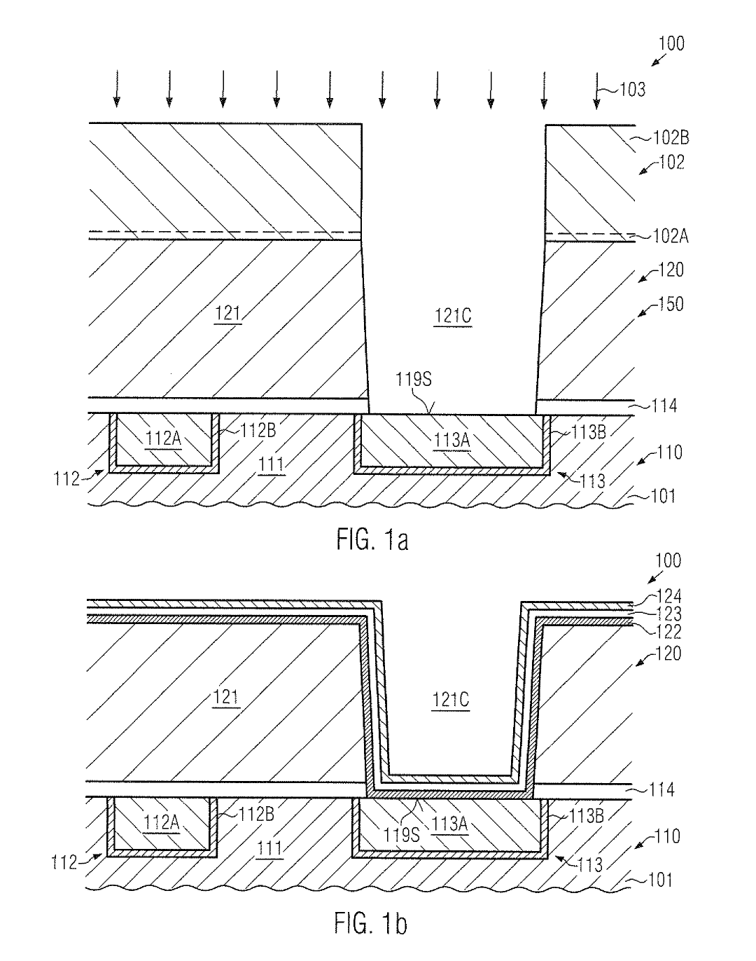

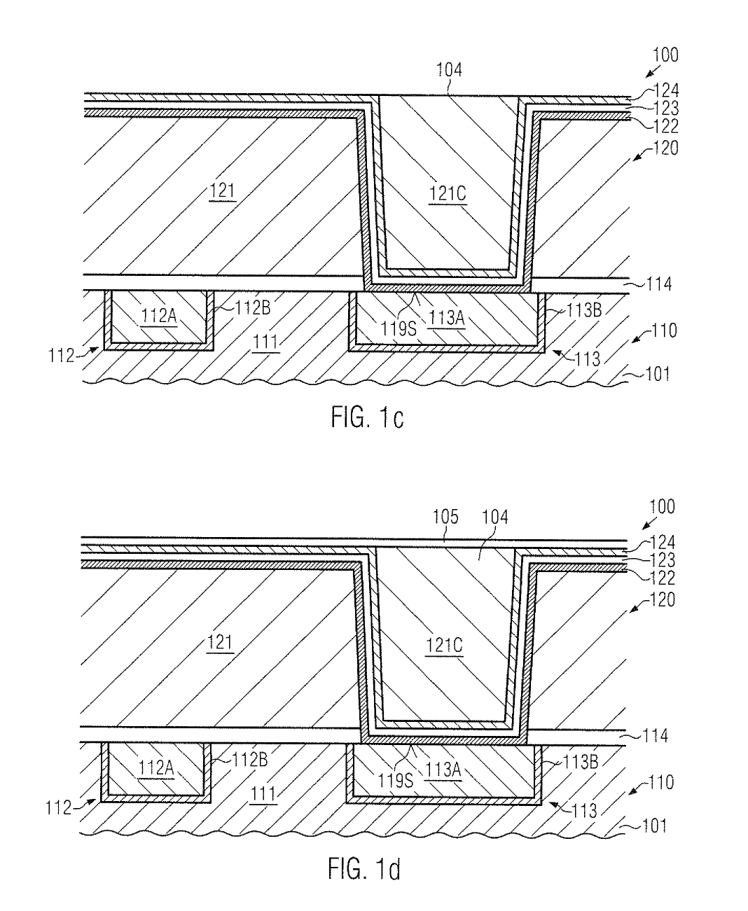

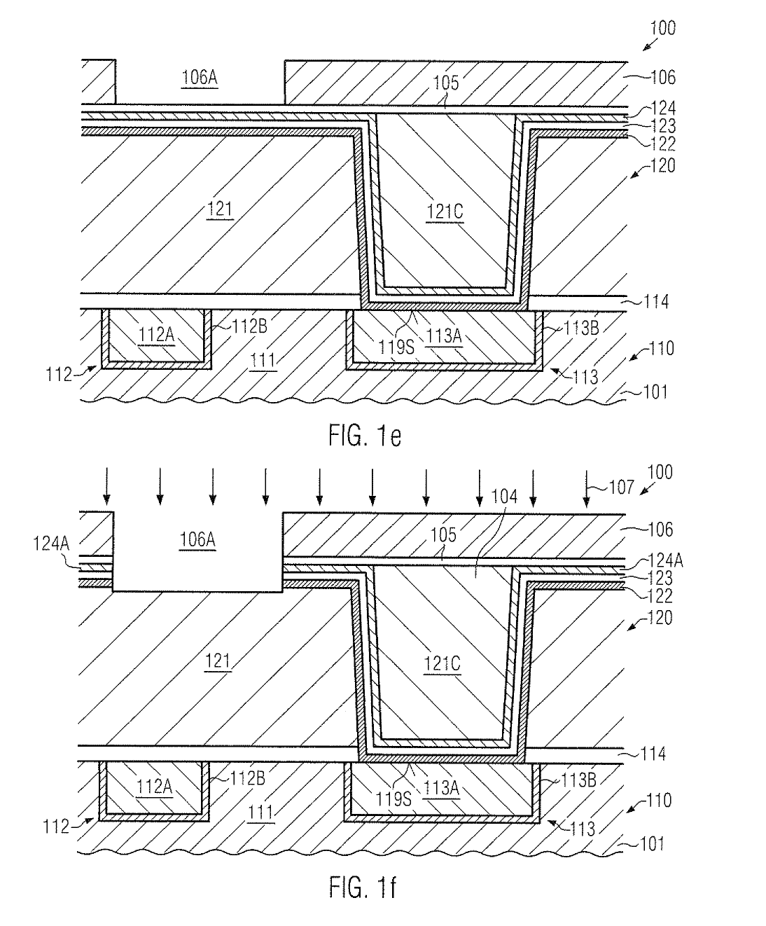

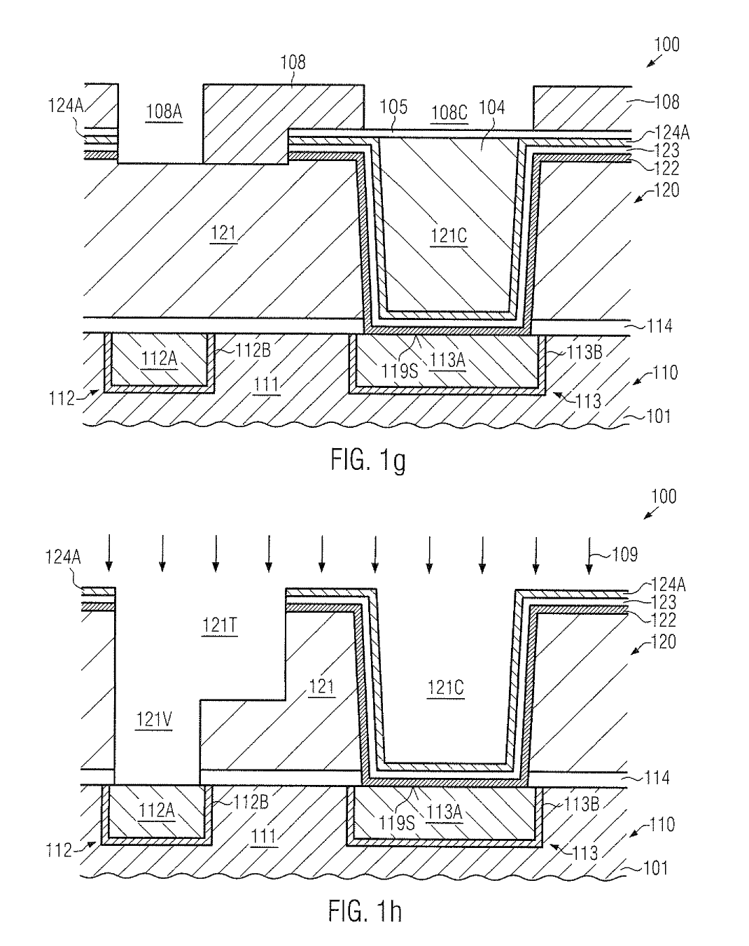

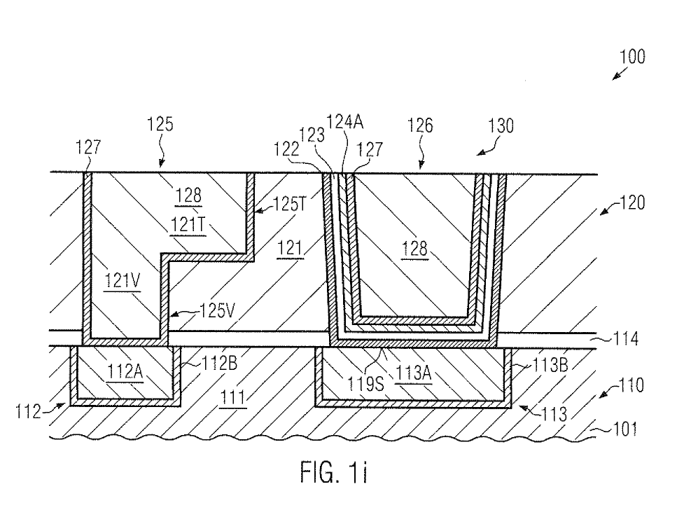

FIG. 1a schematically illustrates a cross-sectional view of a semiconductor device 100 in an advanced manufacturing stage. As illustrated, the semiconductor device 100 may comprise a substrate 101 which may represent any appropriate carrier material for forming therein and thereon circuit elements, such as transistors, resistors, capacitors and the like. For example, the substrate 101 may comprise any appropriate semiconductor material (not shown), such as a silicon material, a silicon/germanium material or any other semiconductor compound, in order to form therein semiconductor-based circuit elements, such as transistors, for instance in the form of field effect transistors, bipolar transistors and the like. For convenience, any such circuit elements are not illustrated in FIG. 1a. It is further to be noted that the semiconductor device 100 may comprise circuit elements, such as field effect transistors, which may be formed on the basis of critical dimensions of approximately 50 nm and less, when sophisticated applications are considered. Moreover, the substrate 101 may have formed thereon (not shown) any appropriate contact regime for connecting the individual circuit elements with a metallization system 150, which is to be understood as a complex network of interconnect structures so as to provide the wiring network for the individual circuit elements on the basis of the circuit layout under consideration. The metallization system 150 of the device 100 may typically be comprised of a plurality of metallization layers, wherein, for convenience, two adjacent metallization layers 110 and 120 are illustrated, at least in part, in FIG. 1a. Thus, it should be appreciated that, above the metallization layer 120 and/or below the metallization layer 110, one or more further metallization layers may be provided, depending on the overall complexity and thus the number of metallization layers required in the metallization system 150. The metallization layer 110 may comprise a dielectric material 111, which may comprise a low-k dielectric material, such as silicon dioxide based materials, polymer materials and the like, possibly in combination with conventional dielectrics, such as silicon dioxide, silicon nitride, nitrogen-enriched silicon carbide and the like. Furthermore, a metal line 112 may be provided and may represent a metal line used for connecting one or more circuit elements (not shown) in accordance with the overall circuit layout. The metal line 112 may comprise a highly conductive core metal or bulk metal 112A in combination with a conductive barrier material 112B, which may provide superior adhesion, diffusion blocking effect and the like. For example, conductive barrier materials, such as tantalum, tantalum nitride, titanium, titanium nitride and the like, may be efficiently used in combination with copper so as to suppress copper diffusion into the surrounding dielectric material and also to suppress the incorporation of reactive species, such as oxygen, fluorine and the like, in the bulk metal 112A. Moreover, the metallization layer 110 may comprise a metal region 113, which may represent an electrode of a capacitor still to be formed in the metallization system 150. Basically, the metal region 113 may have the same configuration in terms of material composition as the metal region 112 and may thus comprise a bulk or core metal 113A, for instance in the form of copper and the like, in combination with a conductive barrier material 113B. On the other hand, the lateral dimensions of the metal region 113 may be selected so as to provide desired area for the capacitor still to be formed and also enable an appropriate contact regime for connecting to the metal region 113.

Moreover, the metallization layer 110 may comprise an etch stop layer 114, which may, in some illustrative embodiments, also act as a dielectric barrier material for confining the bulk metal 112A, 113A, while, in other cases, the metal confinement may be achieved on the basis of a conductive cap material (not shown) which may be provided on the bulk metals 112A, 113A. The etch stop layer 114 may be comprised of silicon nitride, nitrogen-enriched silicon carbide, silicon dioxide and the like, or any combination of these materials.

The metallization layer 120 may comprise a dielectric material 121, such as a low-k dielectric material, depending on the overall requirements with respect to parasitic capacitance and the like, in view of metal lines and vias to be formed in the dielectric material 121 in a later manufacturing stage. Furthermore, the metallization layer 120 may comprise an opening 121C, which may also be referred to as a capacitor opening, which, in the manufacturing stage shown, may extend through the dielectric material 121 and through the etch stop layer 114, thereby exposing a portion of the core metal 113A, as indicated by 119S. It should be appreciated that, in other illustrative embodiments (not shown), the opening 121C may have formed therein a dielectric material, for instance a portion or a sub-layer of the etch stop material 114, which may act as a capacitor dielectric material, possibly in combination with a further material still to be provided in the opening 121C. It should be appreciated that the opening 121C may be referred to as a capacitor opening, which may, however, require a dielectric material, at least at the bottom thereof, so as to provide a dielectric separation with respect to the metal region 113, which acts as a capacitor electrode. Furthermore, as previously explained, the lateral size of the opening 121C may be appropriately selected so as to obtain, in combination with the metal region 113, the desired capacitor area, in combination with the characteristics of a capacitor dielectric still to be formed, the overall capacitance of the resulting capacitor. For example, the capacitance may be selected such that a corresponding stabilization with respect to voltage drops at high transient currents may be accomplished, thereby providing a high decoupling capability for the corresponding capacitors. In other cases, the lateral dimensions are selected such that a sufficient storage capability may be provided as required for storage capacitors of dynamic RAM circuit portions, wherein reduced overall lateral dimensions may result in a superior bit density. On the other hand, any leakage currents may be reduced by providing appropriate dielectric materials, as will be described later on in more detail.

As illustrated, in the manufacturing stage shown, an etch mask 102 may be provided above the dielectric material 121 in order to determine the position and lateral size of the opening 121C.

The semiconductor device 100 as illustrated in FIG. 1a may be formed on the basis of the following processes. Any circuit elements, such as transistors and the like, may be formed on the basis of any appropriate process strategy, wherein, as previously discussed, any complex process sequences for forming deep trenches for capacitors may be omitted, thereby significantly enhancing overall process efficiency. After completing the circuit elements in the device level, an appropriate contact structure may be provided, which may be accomplished by any well-established process techniques. Next, one or more metallization layers may be formed, wherein, when additional capacitor elements are to be provided, similar process strategies may be applied, as will be explained with reference to the metallization layer 120. In other cases, when a corresponding capacitor may not be required in any lower lying metallization levels, the metallization layers may be formed, for instance, by depositing the dielectric material 111 and patterning the same on the basis of appropriate hard mask approaches, as will also be described later on in more detail with reference to the metallization layer 120 when forming vias and trenches therein. Thus, after patterning the dielectric material 111, the metal regions 112, 113 may be formed, for instance, by depositing a barrier material by depositing an appropriate bulk metal so as to provide, after removing any excess materials, the metal regions 112 and 113 including the corresponding barrier layers 112B, 113B, respectively. Next, the etch stop layer 114 may be formed by applying any appropriate deposition techniques, wherein, if desired, two or more sub-layers may be provided, one of which, for instance a bottom layer (not shown), may be used as a gate dielectric material or as a base dielectric material, possibly in combination with an additional dielectric material still to be formed in the opening 121C. Thereafter, the dielectric material 121 may be deposited in accordance with any appropriate process technique and thereafter the etch mask 102 may be formed, for instance by providing a resist mask, which may then be used for patterning the dielectric material 121 during an anisotropic etch process 103 so as to etch into the dielectric material 121. It should be appreciated that the etch mask 102 may be provided as a resist mask since generally the lateral dimensions of the opening 121C may be less critical, for instance compared to the reduced lateral dimensions of metal lines and vias still to be formed in the metallization layer 120. Consequently, an increased thickness of a corresponding resist material may be applied, which may thus provide sufficient etch resistivity during the anisotropic etch process 103. During the etch process 103, the material 114 or at least a portion thereof may be used as an efficient etch stop material, which may be subsequently opened so as to expose the portion 119S, as illustrated in FIG. 1a, while, in other cases, if desired, a portion of the etch stop material 114 may be preserved and may be used as a capacitor dielectric material, or at least a portion thereof.

In other illustrative embodiments, the etch mask 102 may be formed on the basis of a hard mask material 102A, for instance in the form of a conductive or metal-containing hard mask material, such as titanium nitride, tantalum nitride and the like, which may have a very high etch resistivity with respect to the etch chemistry used in the process 103. In this case, a resist mask 102B may be used to pattern the hard mask material 102A, which may then act as an efficient etch stop material for etching the dielectric material 121 and the etch stop layer 114, either completely or partially, as discussed above. Thus, by using the hard mask material 102A, substantially the same patterning regime may be applied as may be used in other metallization layers and as may also be applied to the metallization layer 120 in a later manufacturing stage in order to form therein vias and metal lines. Consequently, well-established process strategies may be applied, wherein an additional lithography process may be applied so as to provide the etch mask 102 that defines the lateral size and position of the capacitor opening 121C.

FIG. 1b schematically illustrates the semiconductor device 100 in a further advanced manufacturing stage. As shown, in some illustrative embodiments, the etch mask 102 (FIG. 1a) may have been removed, while, in other cases, the hard mask material 102A (FIG. 1a) may still be present on horizontal portions of the dielectric material 121 (not shown). Furthermore, a hard mask material 124, such as a conductive hard mask material as specified above, may be formed above the dielectric material 121 and within the opening 121C, wherein a thickness and material composition of the hard mask material 124 may be selected so as to comply with the patterning requirements for forming vias and trenches in the dielectric material 121. Furthermore, in the embodiment shown, a capacitor dielectric material 123 may be provided below the hard mask material 124 and may have any appropriate material composition and thickness so as to comply with the requirements for a capacitor to be formed on the basis of the metal region 113 and the capacitor opening 121C. In some illustrative embodiments, the dielectric material 123 may be comprised of a high-k dielectric material, such as hafnium oxide, hafnium silicon oxide, zirconium oxide, aluminum oxide and the like, with a thickness of one to several nanometers, depending on the required capacitor characteristics. In other illustrative embodiments (not shown), the dielectric material 123 may be omitted if an appropriate dielectric material may still be present at the bottom of the opening 121C, for instance in the form of one or more sub-layers of the etch stop layer 114, as discussed above. In still other illustrative embodiments, any dielectric material residue of the etch stop layer 114 in combination with the dielectric material 123 may act as an appropriate capacitor dielectric. Furthermore, in the embodiment shown, a barrier material 122 may be provided below the hard mask material 124 and the dielectric material 123 so as to appropriately confine the exposed portion 119S of the metal region 113. To this end, any appropriate barrier material, such as tantalum, tantalum nitride and the like, may be used if an additional confinement of a core metal of the metal region 113 is required. In other illustrative embodiments, if confinement is required, the layer 122 may be provided in the form of a dielectric barrier material, such as silicon nitride, nitrogen-enriched silicon carbide and the like, and may act, possibly in combination with the dielectric material 123, as a capacitor dielectric material. Thus, irrespective of the process sequence and the materials used, the metal region 113 may be dielectrically isolated from the hard mask material 124 formed in the opening 121C by one or more dielectric materials, which may thus also act as an efficient capacitor dielectric material.

The materials 122, 123 and 124 may be provided on the basis of well-established deposition techniques, such as plasma enhanced CVD for dielectric materials, atomic layer deposition or cyclic deposition techniques for high-k dielectric materials, sputter deposition, CVD and the like for conductive hard mask materials, and the like. Consequently, the materials 122, 123 and 124 may be provided with high precision, thereby contributing to superior performance of the resulting capacitor since the thickness and material composition of the capacitor dielectric as well as the overall area of the capacitor, i.e., the lateral dimensions of the opening 121C, may be adjusted with superior controllability due to the high etch resistivity of the hard mask material 124.

FIG. 1c schematically illustrates the semiconductor device 100 according to further illustrative embodiments in which a sacrificial fill material 104 may be provided in the opening 121C in order to provide a superior surface topography prior to patterning the dielectric material 121. For example, the sacrificial fill material 104 may be provided in the form of an organic material, which may be provided in a low viscous state by spin-on techniques and the like, thereby reliably filling the opening 121C. If desired, any excess material may be removed, for instance by etch techniques, mild CMP processes and the like, while, in other cases, a corresponding material layer of the excess material may be preserved above the dielectric material 121 and may be used as an efficient anti-reflective coating (ARC) material and the like. It should be appreciated that the sacrificial fill material 104 may be treated in any appropriate manner so as to adjust the overall material characteristics, for instance in terms of hardness, thermal stability and the like. To this end, any appropriate radiation-based treatments, heat treatments and the like may be applied.

FIG. 1d schematically illustrates the semiconductor device 100 according to further illustrative embodiments in which an additional sacrificial cap layer 105, such as a polymer material or any other conventional dielectric materials, such as silicon dioxide and the like, may be formed above the hard mask material 124 and above the sacrificial fill material 104. The dielectric cap material 105 may provide superior integrity of a resist material to be formed in a subsequent manufacturing stage in order to pattern the hard mask material 124. In other cases, the material 105 may be omitted, if considered appropriate in view of the further processing of the device 100. The sacrificial material 105 may be formed on the basis of any appropriate deposition technique, such as plasma enhanced CVD, spin-on techniques and the like.

FIG. 1e schematically illustrates the semiconductor device 100 with an etch mask 106, such as a resist mask, formed above the hard mask material 124 and the material 105, if provided, wherein the etch mask 106 may define the lateral position and size of a trench to be formed in the dielectric material 121. Consequently, a mask opening 106A may have appropriate dimensions for a metal line to be formed in the dielectric material 121, while, on the other hand, the etch mask 106 may be provided with an appropriate layer thickness so as to allow sophisticated lithography processes while the etch resistivity of the mask 106 requires only the patterning of the hard mask layer 124 in combination with the optional layer 105 and possibly of the layers 123, 122, if provided. Consequently, superior resist materials and a reduced layer thickness may be applied as required for obtaining the desired critical dimensions in the metallization layer 120, while the presence of the opening 121C may substantially not affect the process for forming the etch mask 106.

FIG. 1f schematically illustrates the semiconductor device 100 when exposed to an etch process 107, in which the mask opening 106A may be transferred at least into the mask material 124, thereby forming a hard mask 124A. As illustrated, the etch process 107 may also etch through the layers 123 and 122, which may be accomplished on the basis of well-established process recipes. Thereafter, the etch mask 106 may be removed, for instance, by applying well-established resist removal processes, wherein the cap layer 105, if provided, may ensure superior integrity of the fill material 104 in the opening 121C.

FIG. 1g schematically illustrates the semiconductor device 100 in a further advanced manufacturing stage in which a further etch mask 108 may be provided so as to define the lateral size and position of a via opening to be formed in the dielectric material 121. To this end, a resist material may be provided and may be patterned on the basis of appropriate lithography strategies, thereby providing a mask opening 108A within the trench opening of the hard mask 124A, which thus defines the position of a via within a trench, the size and position of which is defined by the hard mask 124A. Furthermore, in the embodiment shown, an opening 108C may be provided so as to substantially correspond to the opening 121C, which may be advantageous during the further processing since the sacrificial fill material 104 may be efficiently removed from the opening 121C, thereby avoiding a significant re-adjustment of any etch parameters which may be selected so as to obtain superior process conditions upon forming a via opening and a trench in the dielectric material 121.

FIG. 1h schematically illustrates the semiconductor device 100 when exposed to an etch ambient 109 in which, at an initial phase (not shown), a via opening may be formed on the basis of the resist mask 108 (FIG. 1g) wherein, upon increasingly consuming the resist material of the mask 108, a trench 121T may be formed in an upper portion of the dielectric material 121, while concurrently increasing a depth of a via opening 121V. At the same time, the sacrificial fill material 104 may be increasingly removed from the opening 121C, while the etch mask 124A, also provided within the opening 121C, may reliably protect any under-lying materials, thereby preserving integrity of the opening 121C, for instance in terms of lateral dimensions and the like. During a final phase of the etch sequence 109, the etch stop layer 114 may be etched, thereby connecting the via opening 121V to the metal region 112. On the other hand, the hard mask 124A may preserve integrity of the dielectric material 123 or of any other dielectric material and of the barrier material 122, if provided, thereby ensuring well-defined electronic characteristics of a capacitor still to be formed on the basis of the metal region 113, the dielectric material 123 and the opening 121C.

Consequently, the etch process sequence 109 may be performed on the basis of any appropriate process conditions, for instance by using well-established process parameters for forming via openings and trenches in a desired metallization level of the semiconductor device 100, while, on the other hand, the presence of the capacitor opening 121C may not negatively influence the overall process sequence or require significant modifications. At the same time, the hard mask 124A may avoid any undue etch damages in the opening 121C. Thereafter, the processing may be continued by forming any appropriate conductive material in the openings 121V, 121T and 121C on the basis of a common process sequence.

FIG. 1i schematically illustrates the semiconductor device 100 in a further advanced manufacturing stage. As illustrated, a metal structure 125 may be formed in the metallization layer 120 and may comprise a metal line 125T and a via 125V, which are formed in the trench 121T and the via opening 121V, respectively. The metal structure 125 may comprise a highly conductive bulk metal 128, such as copper, which may continuously extend from the metal line 125T to the via 125V, while a conductive barrier material 127, such as tantalum, tantalum nitride and the like, may delineate the conductive bulk metal 128 from the surrounding dielectric material 121. Thus, the via 125V may connect to the metal line 112 of the metallization layer 110, thereby establishing the desired electrical connection. Furthermore, the metallization layer 120 may comprise a metal feature 126, which may also be referred to as a capacitor electrode, which may also comprise the conductive barrier material 127 and the bulk metal 128. Furthermore, the metal feature 126 may comprise the conductive hard mask material 124A which may have been used during the previous process sequence for patterning the openings 121T and 121V, as discussed above. Moreover, the metal feature 126 may be dielectrically encapsulated by the dielectric material 123, which may be provided in the form of a high-k dielectric material, a combination of a conventional dielectric material and a high-k dielectric material, a conventional dielectric material and the like, as is also previously discussed. Hence, in the embodiment shown, the dielectric material 123 may also be formed on sidewalls of the metal feature 126, thereby reliably electrically insulating the metal feature 126 from the barrier material 122 which, in some illustrative embodiments, may be provided in the form of a conductive material, which may thus act as an electrode of the capacitor, thereby significantly increasing the total area and hence the capacitance. In other cases, as previously explained, the barrier material 122 may be omitted or may be provided in the form of a dielectric material, thereby forming a capacitor dielectric material, possibly in combination with the material 123, if provided in this case. Consequently, the metal feature 126, the metal region 113 and any dielectric material formed between the metal region 113 and the metal feature 126, such as the dielectric material 123, may represent a capacitor 130, which may be used as a decoupling capacitor, as a storage capacitor and the like, as is also previously explained. It should be appreciated that the bulk metal 128, the conductive barrier material 127 and the conductive hard mask material 124A may represent the electrode material of the capacitor electrode 126, while the bulk metal 113A and the conductive barrier material 113B, possibly in combination with the barrier material 122, if provided as a conductive material, may represent the electrode materials of the capacitor electrode 113. Consequently, the capacitance of the capacitor 130 is defined by the lateral size of the metal feature 126 and the depth thereof, i.e., the size of the sidewalls covered by the barrier material 122, when provided as a conductive material, wherein the lateral dimensions, i.e., the width and length of the feature 126, are defined on the basis of the mask material 124A, thereby ensuring a superior geometric integrity of the metal feature 126. The distance and the dielectric characteristics of the spacing between the electrode 113 and the electrode 126 may also be well defined on the basis of the material 124A, which ensures superior integrity of any dielectric material positioned between the electrode 113 and the electrode 126, as is also previously discussed.

The semiconductor device 100 as illustrated in FIG. 1j may be formed on the basis of the following processes. Starting with the configuration as shown in FIG. 1h, one or more material layers may be deposited in order to provide the conductive barrier material 127, which may be accomplished on the basis of CVD techniques, sputter deposition, electrochemical deposition and the like. Thereafter, any seed materials, if required, may be deposited, followed by the deposition of the bulk metal 128, which may be accomplished by electroplating, electroless plating, a combination thereof and the like. Next, any excess material may be removed by performing electrochemical etching, electro CMP, CMP and the like, thereby also removing the hard mask material 124A, the dielectric material 123 and the barrier material 122 from horizontal areas of the dielectric material 121. To this end, any well-established process recipes may be applied. Consequently, the metal structure 125 and the metal feature 126, i.e., the electrode of the capacitor 130, may be provided as electrically isolated entities in the metallization layer 120 on the basis of well-established process techniques. Thereafter, the further processing may be continued by forming an appropriate cap layer so as to confine the bulk metal 128, for instance in the form of a conductive cap material, a dielectric etch stop material and the like. Thereafter, any further metallization layers, if required, may be provided, wherein, if required, any additional capacitors may be formed therein, which may be accomplished on the basis of similar process techniques as described above with reference to the capacitor 130.

As a result, the present disclosure provides semiconductor devices including capacitors in the metallization system, wherein the electrodes of the capacitor may be formed in compliance with patterning strategies that are also applied when forming metal structures in the metallization layers under consideration. That is, one capacitor electrode may be formed together with metal lines in one metallization layer, while a further capacitor electrode may be formed on the basis of an additional lithography process in which an opening may be formed in the dielectric material of a subsequent metallization layer prior to actually patterning the metal structures therein. The patterning of the metal structure may then be accomplished on the basis of any appropriate hard mask regime, wherein the hard mask material may efficiently protect the previously formed capacitor opening during the further processing. Due to the high etch resistivity of hard mask material within the capacitor opening, integrity of any underlying dielectric material may be reliably preserved and also the dimensional configuration of the capacitor opening may be maintained throughout the entire patterning process, thereby providing well-defined capacitor characteristics after filling in the conductive material without having to remove the hard mask material from the capacitor opening. Consequently, capacitors with well-defined capacitance may be formed without requiring separate process modules, while only one additional lithography mask may be required. The formation of the capacitor electrodes is compatible with the efficient patterning strategy for forming metal structures in the metallization system without requiring significant modifications. Hence, superior performance in combination with reduced production costs may be accomplished on the basis of the principles disclosed herein.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first opening in a dielectric material of a first metallization layer of a semiconductor device, said first opening being positioned above a first metal region formed in a second metallization layer that is formed below said first metallization layer, said first opening being separated from said first metal region by an insulating layer;
forming a conductive hard mask material above said dielectric material of said first metallization layer and above inner surface areas of said first opening;
patterning said conductive hard mask material so as to form a hard mask that defines a size and position of a second opening to be formed in said dielectric material of said metallization layer;
forming said second opening in said dielectric material of said first metallization layer by using said hard mask as an etch stop material; and
filling said first and second openings with a metal-containing material by performing a common fill process.

2. The method of claim 1, wherein forming said first opening comprises etching through said dielectric material so as to connect to said first metal region and forming a dielectric material above said first metal region.

3. The method of claim 2, wherein forming said dielectric material comprises depositing a high-k dielectric material.

4. The method of claim 2, wherein forming said first opening further comprises forming a conductive barrier material on an exposed portion of said first metal region prior to forming a dielectric material above said first metal region.

5. The method of claim 1, further comprising filling said first opening with a sacrificial fill material after forming said hard mask material and prior to patterning said hard mask material.

6. The method of claim 1, wherein forming said second opening comprises forming a via opening and a trench in said dielectric material, wherein said via opening extends to a second metal region of said second metallization layer.

7. The method of claim 1, wherein forming said first opening comprises forming a further hard mask above said dielectric material of said first metallization layer and using said further hard mask to pattern said dielectric material.

8. A method of forming a capacitive structure in a metallization system of a semiconductor device, the method comprising:
forming a capacitor opening in a dielectric layer by performing a first etch process, said capacitor opening being separated from a first capacitor region by a dielectric material;
forming a hard mask above said dielectric layer and in said capacitor opening, said hard mask defining a size and position of a trench;
forming a via opening and said trench by performing a second etch process and using said hard mask as an etch stop material; and
filling said via opening, said trench and said capacitor opening with a metal-containing material in a common process sequence so as to form a via, a metal line connected thereto and a second capacitor region.

9. The method of claim 8, wherein forming said capacitor opening comprises performing said first etch process so as to etch to said first capacitor region and depositing a dielectric material above said first capacitor region.

10. The method of claim 9, wherein said dielectric material comprises a high-k dielectric material.

11. The method of claim 9, further comprising forming a conductive barrier material on an exposed portion of said first capacitor region prior to depositing said dielectric material.

12. The method of claim 8, wherein forming said hard mask comprises depositing a conductive hard mask material and patterning said conductive hard mask material.

13. The method of claim 12, further comprising removing a portion of said hard mask formed above said dielectric layer and preserving said hard mask in said capacitor opening.

14. The method of claim 9, wherein forming said dielectric material comprises depositing a copper diffusion blocking material.

15. The method of claim 12, further comprising filling said capacitor opening with a sacrificial fill material after depositing said conductive hard mask material and prior to patterning the same.

16. A semiconductor device, comprising:
a first metallization layer comprising a first dielectric material and a first metal region embedded in said first dielectric material, said first metal region representing a first capacitor electrode;
a second metallization layer formed below said first metallization layer and comprising a second dielectric material, said second metallization layer comprising a second metal region located below said first metal region and representing a second capacitor electrode; and
a capacitor dielectric material formed on sidewalls and a bottom of said first metal region.

17. The semiconductor device of claim 16, further comprising a hard mask material formed on said capacitor dielectric material.

18. The semiconductor device of claim 17, further comprising a first conductive barrier layer formed on said hard mask material.

19. The semiconductor device of claim 18, further comprising a second conductive barrier layer formed at least between said capacitor dielectric material and a bulk metal material of said second metal region.

20. The semiconductor device of claim 16, further comprising a via and a first metal line formed in said first metallization layer, wherein said via and said first metal line comprise a common bulk metal region and wherein said via extends to a metal line of said second metallization layer.
